(19) United States
(12) Patent Application Publication
(10) Pub. No.: US 2023/0386962 A1
(43) Pub. Date: Nov. 30, 2023

(54) NATURAL CONVECTION INDUCTION HEAT SLUG DESIGN AND SEMICONDUCTOR PACKAGE EQUIPPED WITH THE SAME

(71) Applicant: TELECHIPS INC., Gyeonggi-do (KR)

(72) Inventors: Cheoljin Soo PARK, Gyeonggi-do (KR); Moonsung KIM, Gyeonggi-do (KR); Daehee Rae KIM, Seoul (KR); Donghoon AHN, Gyeonggi-do (KR)

(21) Appl. No.: 18/255,415

(22) PCT Filed: Nov. 11, 2021
(86) PCT No.: PCT/KR2021/016404

§ 371 Date: Jun. 1, 2023

(30) Foreign Application Priority Data
Dec. 2, 2020 (KR) 10-2020-0167003
Mar. 26, 2021 (KR) 10-2021-0039958

(51) Int. Cl. H01L 23/367; H01L 23/467

(52) U.S. Cl. CPC H01L 23/3675; H01L 23/467

(57) ABSTRACT

Disclosed is a heat slug design including: a heat slug design body implemented to be larger than or the same as an area of a substrate, and including a contact area formed at a center of the heat slug design body, and directly/indirectly contacting a silicon die formed on the substrate, a plurality of fixation portions formed on an outer periphery of the heat slug design body, and directly contacting the substrate, and a plurality of opening portions formed between the plurality of fixation portions on the outer periphery of the heating sink body, and having a space having a predetermined height from the substrate.

### TECHNICAL FIELD

The present disclosure relates to a natural convection induction heat slug design and a semiconductor package with the same.

### BACKGROUND ART

Electronic packaging plays a role in protecting semiconductor chips from external environments physically, chemically and mechanically. In addition, the electronic packaging effectively delivers external signals or power into the semiconductor chip, which supports the function of the semiconductor chip.

That is, electronic packaging distributes power, distributes signals, or performs heat release and a protection function of the semiconductor chip from the outside. Among them, a function of effectively discharging heat from the semiconductor chip is one of the important features of the electron packaging.

As the integration of devices in the electronic components increases and the devices become light and thin, the increase in heat generated from the device acts as a cause of reducing the reliability of the semiconductor devices. In addition, due to the difference in thermal expansion coefficients of the semiconductor chips and the electronic packaging devices, there can be a problem of reducing the life of the electron packaging device by increasing thermal stress applied to solder and the device connecting a material.

To solve this problem, it is possible to review design modification of the product, addition of a thermal path, or application of a high-performance material as a way to improve heat dissipation. However, in the reflection of these reviews, there is a disadvantage that accompanies the product's appearance and design change, exterior change, and increase in production costs.

### DISCLOSURE

### Technical Problem

Accordingly, the present disclosure attempts to provide a natural convection induction heat slug design and a semiconductor package with the same capable of easily vanishing heat generated by a silicon die by deforming an external shape of a heat slug design.

### Technical Solution

In order to achieve a technical object of the present disclosure, an exemplary embodiment of the present disclosure provides a heat slug design which includes a heat slug design body implemented to be larger than or the same as an area of a substrate, and includes a contact area formed at a center of the heat slug design body, and directly/indirectly contacting a silicon die formed on the substrate, a plurality of fixation portions formed on an outer periphery of the heat slug design body, and directly contacting the substrate, and a plurality of opening portions formed between the plurality of fixation portions on the outer periphery of the heating sink body, and having a space having a predetermined height from the substrate.

The heat slug design body may be implemented in a quadrangular shape.

The plurality of fixation portions may be formed on four sides of the outer periphery of the heat slug design body, respectively.

The plurality of opening portions may be formed at four apexes of the outer periphery of the heat slug design body, respectively.

The plurality of fixation portions may be formed at four apexes of the outer periphery of the heat slug design body, respectively.

The plurality of opening portions may be formed on four sides of the outer periphery of the heat slug design body, respectively.

At least one opening portion of the plurality of opening portions may be an inlet through which wind generated by a cooling fan is introduced, and at least one opening portion of the plurality of opening portions may be an outlet through which the introduced wind is discharged jointly with the heat of the silicon die.

The outlet may release the heat generated from the silicon die to the outside through natural convection by a difference between a temperature of the silicon die and a surrounding temperature of the silicon die.

In order to achieve a technical object of the present disclosure, another exemplary embodiment of the present disclosure provides a semiconductor package which includes: a substrate which has a circuit pattern, and is a quadrangular plane; a silicon die formed on the substrate, and electrically connected to the substrate; and a heat slug design formed at an upper portion of the silicon die, and releasing heat generated from the silicon die to the outside, in which the heat slug design includes a plurality of fixation portions generated by a predetermined length around four apexes of an outer periphery of the heat slug design or with partial lengths of four sides directly contacting the substrate, and a plurality of opening portions formed between respective fixation portions and formed to be spaced apart from the substrate by a predetermined height.

The semiconductor package may further include a cooling fan which operates so as for the wind to be introduced into any one opening portion of the plurality of opening portions.

The heat slug design may release the heat generated from the silicon die to the outside through natural convection by a difference between a temperature of the silicon die and a surrounding temperature of the silicon die through a contact area indirectly/directly contacting the silicon die, and discharge the wind introduced into at least one opening portion of the plurality of opening portions jointly with the heat of the silicon die through at least one opening portion of the plurality of opening portions.

### Advantageous Effects

According to the present disclosure, a heat release effect of a semiconductor chip can be improved by simultaneously applying natural convection and forced convection by a cooling fan by applying an open type shape structure without changing a material and a size of a heat slug design.

In addition, it is possible to ensure the reliability of a product by preventing a package temperature increase when operating through the improvement of heat release.

In addition, it is possible to prevent a flexural defect by a high temperature by maintaining a structure in which at least four points are fixed onto a substrate, and when a heat sink is applied, a more stable heat sink balance can be maintained by the increase in mounting area.

### DESCRIPTION OF THE DRAWINGS

FIG. 1 is an exemplary diagram of a semiconductor package adopting a general sealed heat slug design.

FIG. 2 is an exemplary diagram of a semiconductor package adopting a general opened heat slug design.

FIG. 3 is an exemplary diagram illustrating a semiconductor package according to an exemplary embodiment of the present disclosure.

FIG. 4A and FIG. 4B are exemplary diagrams of an opened heat slug design according to an exemplary embodiment of the present disclosure.

FIG. 5 is an exemplary diagram illustrating a heat flow in a heat slug design according to an exemplary embodiment of the present disclosure.

### MODE FOR INVENTION

In the following detailed description, only certain exemplary embodiments of the present disclosure have been shown and described, simply by way of illustration. As those skilled in the art would realize, the described embodiments may be modified in various different ways, all without departing from the spirit or scope of the present disclosure. Accordingly, the drawings and description are to be regarded as illustrative in nature and not restrictive. Like reference numerals designate like elements throughout the specification.

Throughout the specification, unless explicitly described to the contrary, the word “comprise”, and variations such as “comprises” or “comprising”, will be understood to imply the inclusion of stated elements but not the exclusion of any other elements.

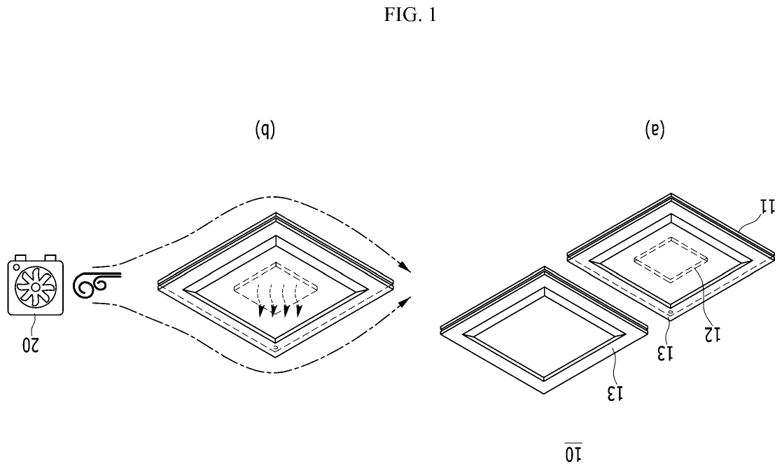

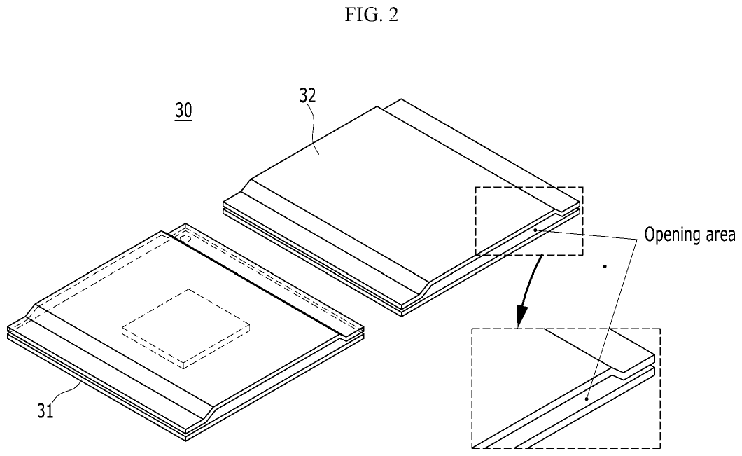

Hereinafter, with reference to drawings, a natural convection induction heat slug design and a semiconductor package with the same according to exemplary embodiments of the present disclosure will be described. Prior to describing an exemplary embodiment of the present disclosure, a general heat slug design is first described with reference to FIGS. 1 and 2.

FIG. 1 is an exemplary diagram of a semiconductor package adopting a general sealed heat slug design.

As shown in FIG. 1A, in a generally-used semiconductor package, a silicon die 12 which is a semiconductor chip is attached to a substrate 11. In addition, a heat slug design 13 is configured to directly/indirectly contact the silicon die 12 in order to protect the silicon die 12 from the outside and release heat generated from the silicon die 12. The silicon die 12 and the heat slug design 13 are in contact with each other, so the heat generated from the silicon die 12 may be transferred through a contact area and released to the outside.

In this case, the heat slug design 13 are in contact with the substrate 11 on four surfaces. Therefore, heat generated from the silicon die 12 may be transferred to the substrate 11 through four contact surfaces which are in contact with the substrate 11 and released to the outside.

However, since the heat slug design 13 and the substrate 11 are attached in a form in which four surfaces are sealed by using a thermal interposer material (TIM), a natural heat flow according to a temperature difference for each location inside the semiconductor package 10, i.e., natural convection is generated inside the semiconductor package 10.

In addition, as shown in FIG. 1B, a cooling fan 20 added for heat release is implemented with a set with the semiconductor package 10. However, there is a constraint in release of heat inside the semiconductor package 10 by forced convection of the cooling fan 20.

That is, a natural heat flow is generated from a high-temperature part to a low-temperature part, and the result convection circulation should be conducted, but in the case of a sealed structure, the convection circulation is impossible. As a result, the heat transfer by the natural convection is impossible, and a sealed internal temperature reaches a heat saturation state after an operation is conducted during a predetermined period.

FIG. 2 is an exemplary diagram of a semiconductor package adopting a general opened heat slug design.

As shown in FIG. 2, the opened heat slug design 32 is implemented in a form in which two surfaces facing each other are in close contact with the substrate 31, and two other surfaces facing each other are spaced apart from the substrate 31 to form an opening area. The semiconductor package 30 adopting the opened heat slug design 32 may expect the effectiveness of the natural convection and the forced convection by the cooling fan as compared with the semiconductor package 10 with the sealed heat slug design 13 of FIG. 1.

However, since only two surfaces of the heat slug design 31 are bonded to the substrate 31 in the semiconductor package 30, the semiconductor package 30 has a mechanical vulnerability such as an increase in package warpage by a change of a welding temperature (reflow temp) upon surface mounter technology (SMT). This may cause an electrical open or short failure between the semiconductor package 30 and a board such as non-wet or solder bridge between a solder ball and a board (not shown).

Therefore, an exemplary embodiment of the present disclosure proposes an opened heat slug design that may minimize warpage generation between low-temperature and high-temperature areas by increasing a fixation part between the semiconductor package and the heat slug design while maintaining a structure the opened heat slug design through a heat slug design having deformed fixed points of four surfaces and four opening portions.

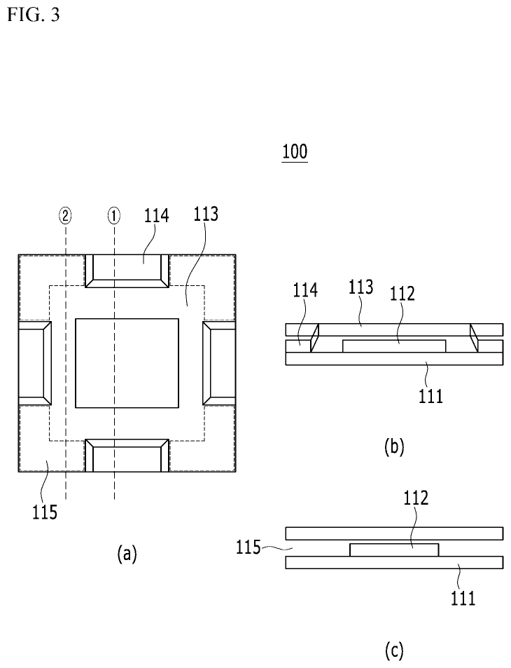

FIG. 3 is an exemplary diagram illustrating a semiconductor package according to an exemplary embodiment of the present disclosure.

As shown in FIGS. 3A to 3C, a semiconductor package 100 according to one exemplary embodiment includes a substrate 111 which has a circuit pattern and is a rectangular plane, and a silicon die 112 formed on the substrate 111 by a bonding member such as epoxy or an adhesive film, similarly to a general substrate. The silicon die 112 may be electrically connected to the substrate 111 by using a wire (not shown) or electrically connected to the substrate 111 by a flipchip bonding scheme.

The opened heat slug design includes a heat slug design body 113 and a fixation module 114. The heat slug design body 113 is larger than or the same as an area of the substrate 111 and is installed on a top surface of the silicon die 112 to protect the silicon die 112.

In an exemplary embodiment of the present disclosure, for convenience of description, it is shown that the heat slug design includes a rectangular heat slug design body 113, a plurality of fixation portions 114 having a predetermined length, which is provided at a lower end of the heat slug design body 113 and fixed to the substrate 111, and a plurality of opening portions 115 not fixed to the substrate 111.

In an exemplary embodiment of the present disclosure, for convenience of description, it is described as an example that the heat slug design body 113 is quadrangle, but if the heat slug design body 113 is installed on the top surface of the silicon die 112 and is larger than or the same as the area of the substrate 111, the heat slug design body 113 may be implemented even in a polygonal shape. In addition, it is described as an example that in the heat slug design body 113, a copper (Cu) material is coded with nickel (Ni), but there is no separate constraint in the material of the heat slug design body 113.

A cross section of position \textcircled{1} of FIG. 3A is shown in FIG. 3B, and a cross section of position \textcircled{2} of FIG. 3A is shown in FIG. 3C. The fixation portion 114 is provided at position \textcircled{1}, so the fixation portion 114 is positioned between the substrate 111 and the heat slug design body 113 as shown in FIG. 3B. On the contrary, since the opening portion 115 is implemented at position \textcircled{3}, a space through which heat may be released may be formed between the substrate 111 and the heat slug design body 113 as shown in FIG. 3C.

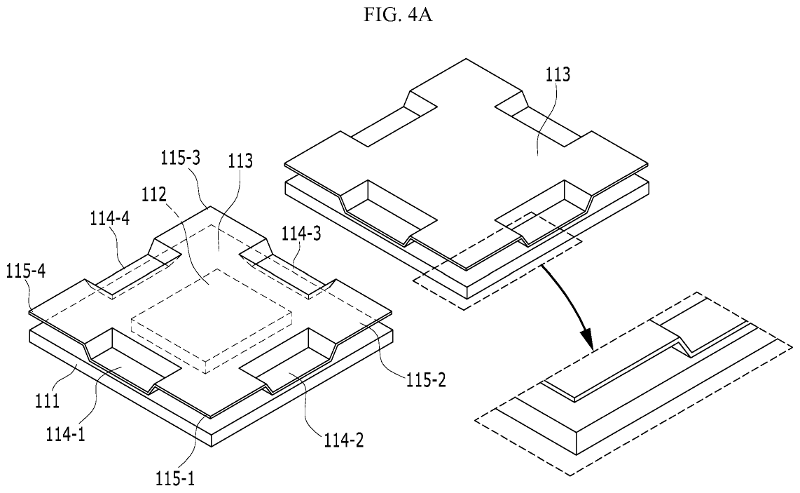

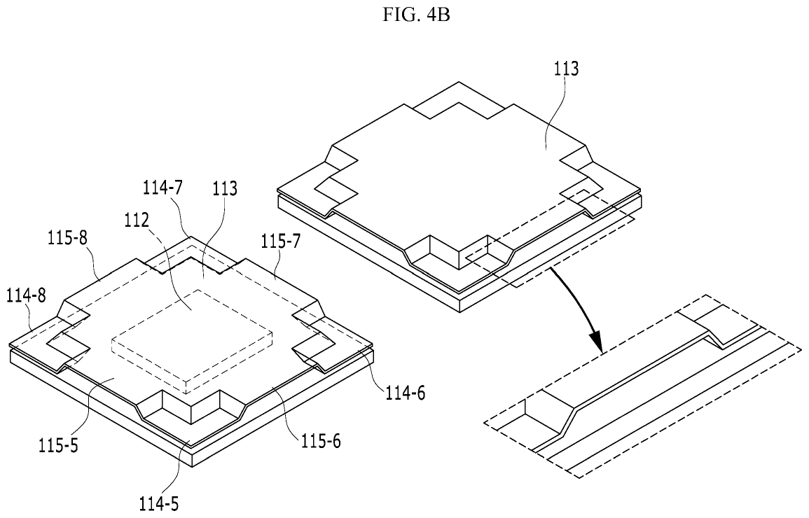

An example of the position of the opening portion of the opened heat slug design will be described with reference to FIGS. 4A and 4B.

FIG. 4A and FIG. 4B are exemplary diagrams of an opened heat slug design according to an exemplary embodiment of the present disclosure.

First, as shown in FIG. 4A, the opened heat slug design of the semiconductor package 100 according to one exemplary embodiment has a quadrangular heat slug design body 113 which is larger than or the same as the area of the substrate 111. Fixation portions 114, 114-1 to 114-4 having a predetermined length are formed in a predetermined areas of four sides of the heat slug design body 113, and opening portions 115, 115-1 to 115-4 are formed up to a side where the fixation portion 114 is formed based on a vertex portion of the heat slug design body 113.

The fixation portion 114 as an area directly contacting the substrate 111 is formed with a predetermined length based on a center of each side of the heat slug design body 113. In an exemplary embodiment of the present disclosure, it is described as an example that the fixation portion 114 is formed with a predetermined length based on a center of each side of the heat slug design body 113, but the fixation portion 114 may also be formed close to one apex portion. In addition, in an exemplary embodiment of the present disclosure, it is described as an example that the fixation portion 114 is formed at four points of the heat slug design body 113, but four points or more may be formed.

The opening portion 115 is not in contact with the substrate 111, so the heat generated from the silicon die 112 is naturally convected and released to the outside. To this end, the opening portion 115 is implemented to be spaced apart from the substrate 111 by a predetermined height.

At least one opening portion of a first opening portion 115-1 to a fourth opening portion 115-4 is an inlet through which wind generated by the cooling fan installed for the forced convection is introduced and the remaining opening portion is an outlet through which the heat generated from the silicon die 112 is discharged jointly with the wind. To this end, it is described as an example that the first opening portion 115-1 and a third opening portion 115-3 are implemented to face each other and a second opening portion 115-2 and the fourth opening portion 115-4 are implemented to face each other. However, a length and a position of the opening portion may also be implemented to be different according to a wind direction of the cooling fan installed for the forced convection.

When a configuration method is described by taking the first opening portion 115-1 as an example, a first part of the first opening portion 115-1 is connected to one side of a first fixation portion 114-1 of the first opening portion 115-1 around the apex portion of the heat slug design body 113, and a second part of the first opening portion 115-1 is connected to one side of a second fixation portion 114-2. Similarly, the second opening portion 115-2 to the fourth opening portion 115-4 are also formed in the same form.

Here, the length of the fixation portion or the height of the opening portion is not limited to any one numerical value.

Meanwhile, as shown FIG. 4B, fixation portions 114, 114-5 to 114-8 having a predetermined length are formed around the apex portion of the heat slug design body 113 of the semiconductor package 100 according to another exemplary embodiment, and opening portions 115, 115-5 to 115-8 are formed in predetermined areas of four sides of the heat slug design body 113.

The opening portions 115, 115-5 to 115-8 are not in contact with the substrate 211, so the heat generated from the silicon die 212 is naturally convected and released to the outside. To this end, the opening portion 115 is implemented to be spaced apart from the substrate 211 by a predetermined height.

The opening portion 115 is formed with a predetermined length around the center of each side of the heat slug design body 113. In an exemplary embodiment of the present disclosure, it is described as an example that the opening portion 115 is formed with a predetermined length based on a center of each side of the heat slug design body 113, but the opening portion 115 may also be formed close to one apex portion.

The fixation portions 114, 114-5 to 114-8 as an area directly contacting the substrate 111 is formed with a predetermined length based on the apex portion of the heat slug design body 113. When a configuration method is described by taking the first fixation portion 114-5 as an example, a first part of the first fixation portion 114-5 is connected to one side of the first opening portion 115-5 around the apex portion of the heat slug design body 113, and a second part of the first fixation portion 114-5 is connected to one side of the second opening portion 115-6. Similarly, the second fixation portion 114-6 to the fourth fixation portion 114-8 are also formed in the same form.

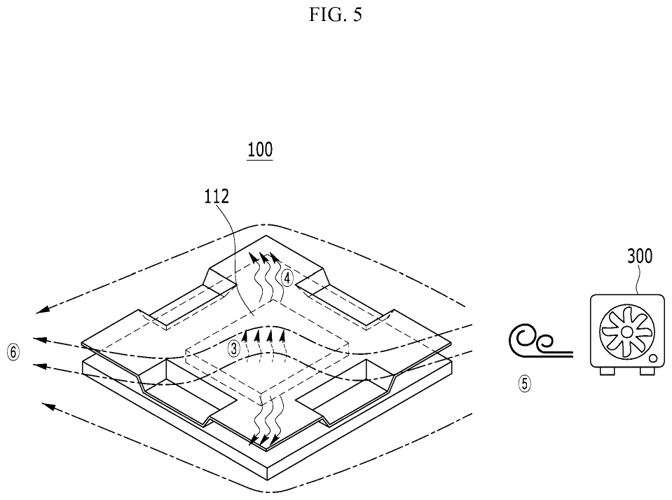

The flow of the heat in the semiconductor package including the heat slug design implemented by the exemplary embodiments will be described with reference to FIG. 5. In FIG. 5, it is described as an example that the heat slug design in which the opening portion is implemented at the apex portion is included in the semiconductor package.

FIG. 5 is an exemplary diagram illustrating a heat flow in a heat slug design according to an exemplary embodiment of the present disclosure.

As shown in FIG. 5, when the heat is released from the silicon die 112 (\textcircled{3}), heat generated from the silicon die 112 is released through the opening portion of the heat slug design 113 by the natural convection by a temperature difference between the silicon die 112 and a surrounding inside the semiconductor package 100 (\textcircled{4}). In addition, when the cooling fan 300 operates and the forced convection is generated, the wind is introduced into the inlet among the opening portions of the heat slug design 113 (\textcircled{5}), and the window moves to the outlet among the opening portions jointly with the heat generated from the silicon die 112, so the heat is released to the outside (\textcircled{6}).

As such, a heat release effect of the semiconductor chip can be improved by simultaneously applying the natural convection and the forced convection by the cooling fan by applying an open type shape structure without changing the material and the size of the heat slug design.

While the embodiments of the present disclosure have been described above in detail, it is to be understood that the scope of the present disclosure is not limited to the disclosed embodiments, but, on the contrary, is intended to cover various modifications and equivalent arrangements included within the spirit and scope of the appended claims.

1. A heat slug design comprising:
a heat slug design body implemented to be larger than or the same as an area of a substrate,
a contact area formed at a center of the heat slug design body, and directly/indirectly contacting a silicon die formed on the substrate,
a plurality of fixation portions formed on an outer periphery of the heat slug design body, and directly contacting the substrate, and
a plurality of opening portions formed between the plurality of fixation portions on the outer periphery of the heating sink body, and having a space having a predetermined height from the substrate.

2. The heat slug design of claim 1, wherein:
the heat slug design body is implemented in a quadrangular shape.

3. The heat slug design of claim 2, wherein:
the plurality of fixation portions
are formed on four sides of the outer periphery of the heat slug design body, respectively.

4. The heat slug design of claim 3, wherein:
the plurality of opening portions,
are formed at four apexes of the outer periphery of the heat slug design body, respectively.

5. The heat slug design of claim 2, wherein:
the plurality of fixation portions
are formed at four apexes of the outer periphery of the heat slug design body, respectively.

6. The heat slug design of claim 5, wherein:
the plurality of opening portions,
are formed on four sides of the outer periphery of the heat slug design body, respectively.

7. The heat slug design of claim 1, wherein:
at least one opening portion of the plurality of opening portions is an inlet through which wind generated by a cooling fan is introduced, and
at least one opening portion of the plurality of opening portions is an outlet through which the introduced wind is discharged jointly with the heat of the silicon die.

8. The heat slug design of claim 7, wherein:
the outlet,
releases the heat generated from the silicon die to the outside through natural convection by a difference between a temperature of the silicon die and a surrounding temperature of the silicon die.

9. A semiconductor package comprising:
a substrate which has a circuit pattern, and is a quadrangular plane;
a silicon die formed on the substrate, and electrically connected to the substrate; and
a heat slug design formed at an upper portion of the silicon die, and releasing heat generated from the silicon die to the outside,
wherein the heat slug design
includes a plurality of fixation portions generated by a predetermined length around four apexes of an outer periphery of the heat slug design or with partial lengths of four sides directly contacting the substrate, and a plurality of opening portions formed between respective fixation portions and formed to be spaced apart from the substrate by a predetermined height.

10. The semiconductor package of claim 9, further comprising:
a cooling fan which operates so as for the wind to be introduced into any one opening portion of the plurality of opening portions.

11. The semiconductor package of claim 9,
wherein the heat slug design
releases the heat generated from the silicon die to the outside through natural convection by a difference between a temperature of the silicon die and a surrounding temperature of the silicon die through a contact area indirectly/directly contacting the silicon die, and
discharges the wind introduced into at least one opening portion of the plurality of opening portions jointly with the heat of the silicon die through at least one opening portion of the plurality of opening portions.
